(19) United States
(12) Patent Application Publication
(10) Pub. No.: US 2025/0324575 A1
(43) Pub. Date: Oct. 16, 2025

(54) SEMICONDUCTOR DEVICE AND METHOD OF FORMING THE SAME

(71) Applicant: NANYA TECHNOLOGY CORPORATION, New Taipei city (TW)

(72) Inventors: Chih-Chun HSIAO, New Taipei City (TW); Ji-Feng LIU, New Taipei City (TW)

(21) Appl. No.: 18/631,791

(22) Filed: Apr. 10, 2024

(51) Int. Cl. H10B 12/00

(52) U.S. Cl. CPC H10B 12/485; H10B 12/02

(57) ABSTRACT

A semiconductor device includes a substrate including a plurality of active regions and an isolation region between the active regions, a plurality of bit line structures disposed on the active regions; a plurality of spacer structures disposed on sidewalls of the bit line structures; a buried contact disposed between the bit line structures; a barrier layer disposed above the buried contact and on sidewalls of spacer structures; a metal silicide layer disposed on the buried contact; a metal nitride layer disposed on the metal silicide layer; and a landing pad disposed on the metal nitride layer. A method of forming the semiconductor structure is also disclosed.

### BACKGROUND

### Field of Invention

The present disclosure relates to a semiconductor device and method of forming the same.

### Description of Related Art

Smaller and lighter electronics devices have driven semiconductor devices shirked with a high degree of integration. The highly compact semiconductor devices result in limited space for element configuration. For example, a landing pad is configured in a conventional dynamic random access memory (DRAM) cells for a purpose of electrical interconnection. As the DRAM technology node shrunk, a high aspect ratio of filling contact holes may lead to void in the contact, which increases the resistance and decreases the current, thereby influencing performance of the DRAM cells.

### SUMMARY

An aspect of the disclosure provides a semiconductor device. The semiconductor device includes a substrate including a plurality of active regions and an isolation region between the active regions, a plurality of bit line structures disposed on the active regions; a plurality of spacer structures disposed on sidewalls of the bit line structures; a buried contact disposed between the bit line structures; a barrier layer disposed above the buried contact and on sidewalls of spacer structures; a metal silicide layer disposed on the buried contact; a metal nitride layer disposed on the metal silicide layer; and a landing pad disposed on the metal nitride layer.

According to some embodiments of the disclosure, a side surface of the buried contact is in contact with the spacer structures.

According to some embodiments of the disclosure, the metal silicide layer includes a lower section and an upper section, the lower section is embedded in the buried contact, and the upper section is protruded from the buried contact.

According to some embodiments of the disclosure, a side surface of the upper section is in contact with the barrier layer.

According to some embodiments of the disclosure, a top surface of the upper section is higher than a top surface of the buried contact.

According to some embodiments of the disclosure, a width of the metal silicide layer is less than a width of the buried contact.

According to some embodiments of the disclosure, a side surface of the metal nitride layer is in contact with the barrier layer, and an interface is present between the metal nitride layer and the barrier layer.

According to some embodiments of the disclosure, the buried contact includes polysilicon, the metal silicide layer is a titanium silicide layer, the metal nitride layer is a titanium nitride layer, and the landing pad includes tungsten.

Another aspect of the disclosure provides a method of forming a semiconductor device. The method includes forming a plurality of bit line structures on a plurality of active regions of a substrate; forming a plurality of spacer structures on sidewalls of the bit line structures; forming a buried contact between the bit line structures; forming a barrier layer disposed on a top surface of the buried contact and on sidewalls of spacer structures; removing a portion of the barrier layer on the top surface of the buried contact to expose the top surface of the buried contact; forming a metal silicide layer on the buried contact; forming a metal nitride layer on the metal silicide layer; and forming a landing pad disposed on the metal nitride layer.

According to some embodiments of the disclosure, the barrier layer is formed by performing an advanced sequential flow deposition process.

According to some embodiments of the disclosure, the advanced sequential flow deposition process includes performing a plurality of cycles of following steps: providing titanium tetrachloride (TiCl₄) gas to the chamber; introducing a first purge gas to remove excess TiCl₄ gas from the chamber; providing ammonia (NH₃) gas to the chamber; and introducing a second purge gas to remove excess NH₃ gas from the chamber.

According to some embodiments of the disclosure, the metal silicide layer is formed by performing a selective deposition process to deposit metal on the top surface of the buried contact, and the deposited metal is reacted with a silicon material of the buried contact.

According to some embodiments of the disclosure, the selective deposition process further deposits a metal layer on the metal silicide layer.

According to some embodiments of the disclosure, the method further includes performing a nitridation process to transform the metal layer to a metal nitride layer.

According to some embodiments of the disclosure, the buried contact includes polysilicon, the metal silicide layer is a titanium silicide layer, the metal nitride layer is a titanium nitride layer, and the landing pad includes tungsten.

It is to be understood that both the foregoing general description and the following detailed description are by examples, and are intended to provide further explanation of the disclosure as claimed.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is an arrangement diagram of a semiconductor device according to some embodiments of the present disclosure.

FIG. 2 to FIG. 9 are cross-sectional views illustrating different steps of a method of forming a semiconductor device in accordance with some embodiments of the present disclosure.

### DESCRIPTION OF THE EMBODIMENTS

Reference will now be made in detail to the present embodiments of the disclosure, examples of which are illustrated in the accompanying drawings. Wherever possible, the same reference numbers are used in the drawings and the description to refer to the same or like parts.

It will be understood that when an element is referred to as being “on” another element, it can be directly on the other element or intervening elements may be presented therebetween. In contrast, when an element is referred to as being “directly on” another element, there are no intervening elements present. As used herein, the term “and/or” includes any and all combinations of one or more of the associated listed items. Reference will now be made in detail to the present embodiments of the disclosure, examples of which are illustrated in the accompanying drawings. Wherever possible, the same reference numbers are used in the drawings and the description to refer to the same or like parts.

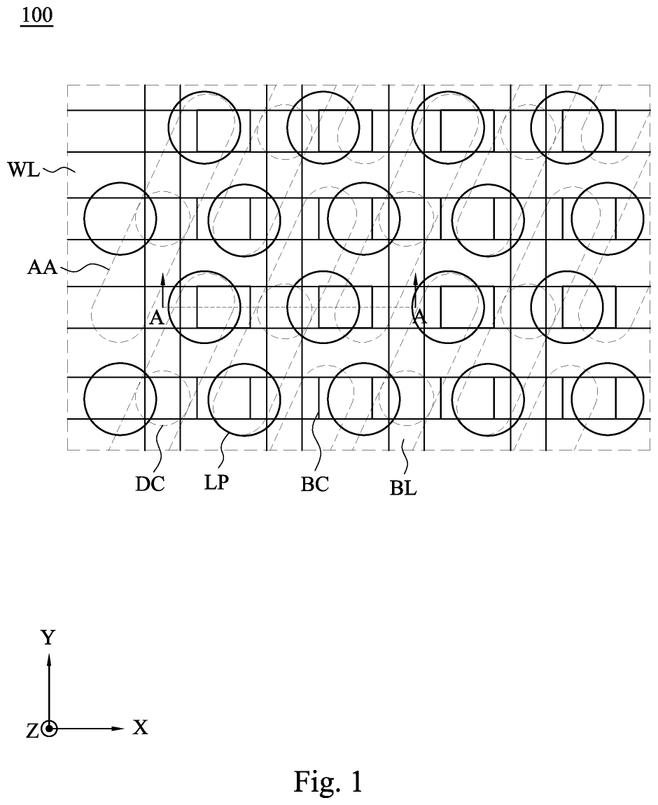

Reference is made to FIG. 1. FIG. 1 is an arrangement diagram of a semiconductor device according to some embodiments of the present disclosure. The semiconductor device 100 may include a plurality of active areas AA. In some embodiments, each of the active area AA has a short axis and a long axis and is in a shape of ellipse in a top view. In some embodiments, the long axis of the active area AA may extend in a diagonal axis with respect to an X axis.

A plurality of word lines WL are configured across the active areas AA and extend along the X axis. The word lines WL are in parallel to each other. Additionally, the word lines WL may be spaced apart from each other at substantially equal intervals.

A plurality of bit lines BL are arranged above the word lines WL and may extend along a Y axis. Similarly, the lines BL are in parallel to each other. In addition, the bit lines BL can be connected to the corresponding active areas AA through direct contacts DC. In some embodiments, one active area AA may be electrically connected to one direct contacts DC.

A plurality of buried contacts BC may be formed between two adjacent bit lines BL. In some embodiments, the buried contacts BC may be spaced apart from each other along the Y axis. The buried contact BC may electrically connect a lower electrode of the capacitor (not shown) to a corresponding active area ACT. One active area ACT may be electrically connected to two buried contacts BC.

A plurality of buried contacts BC may be formed between two adjacent bit lines BL. In some embodiments, the buried contacts BC may be spaced apart from each other along the Y axis.

A plurality of landing pads LP are disposed on the buried contacts BC and overlap at least a portion of the corresponding bit lines BL. The landing pads LP may electrically connect the buried contacts BC. Also, the landing pads LP may also electrically connect the lower electrode of the capacitor (not shown) to a corresponding active area AA. The landing pads LP with the buried contacts BC together serve as contact plugs to electrically connect the capacitors to the corresponding active areas AA. The capacitor and the corresponding transistor including the active areas AA can be regarded as a 1T1C memory cell.

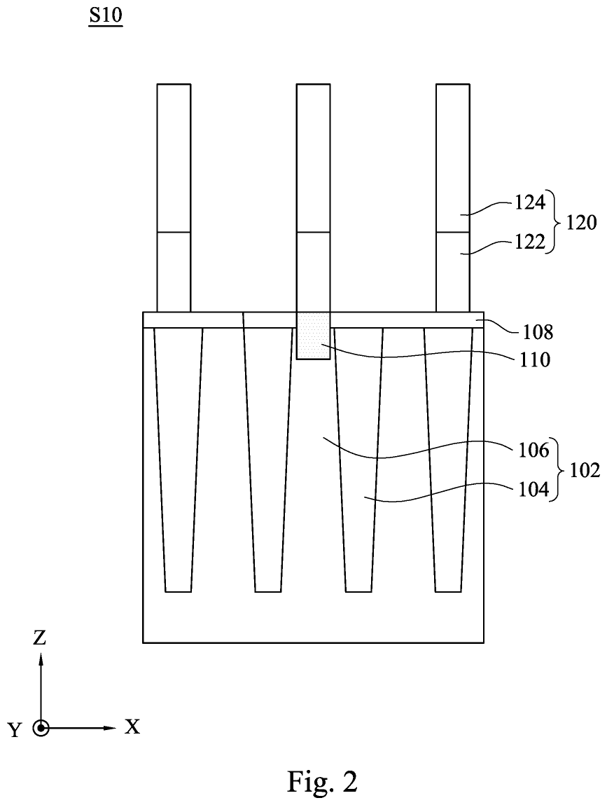

Reference is made to FIG. 2 to FIG. 9. FIG. 2 to FIG. 9 are cross-sectional views illustrating different steps of a method of forming a semiconductor device in accordance with some embodiments of the present disclosure. The cross-section views of FIG. 2 to FIG. 9 are based on a reference cross-sectional view taken along line A-A shown in FIG. 1.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

Referring to FIG. 2, the method of forming the semiconductor structure begins at step S10, a plurality of bit line structures 120 are formed over a substrate 102.

The substrate 102 includes a plurality of isolation areas 104 and a plurality of active areas 106. The substrate 102 may include, for example, silicon (e.g., crystalline silicon, polycrystalline silicon, or amorphous silicon). In some embodiments, the substrate 102 may include other elementary semiconductor such as germanium. In some embodiments, the substrate 102 may include an alloy semiconductor such as silicon germanium, silicon germanium carbide, gallium indium phosphide and the like. In some embodiments, the substrate 102 may include compound semiconductor such as gallium arsenic, silicon carbide, indium phosphide, indium arsenide and the like. Further, the substrate 102 may optionally include a semiconductor-on-insulator (SOI) structure. The active areas 106 may be doped regions of the substrate 102, and the active areas 106 are spaced apart by the isolation areas 104.

The isolation areas 104 may be formed through a shallow trench isolation (STI) process. The isolation areas 104 may include, for example, a material including at least one of silicon oxide, silicon nitride, and silicon oxynitride. The isolation areas 104 may be a single layer including one kind of insulator, a double layer including two kinds of insulators, or a multilayer including a combination of at least three kinds of insulators. For example, the isolation areas 104 may include silicon oxide and silicon nitride. For example, the isolation areas 104 may include a triple layer including silicon oxide, silicon nitride, and silicon oxynitride.

An insulation layer 108 is formed on the substrate 102 and covers top surfaces of the isolation areas 104 and the active areas 106 of the substrate 102. The insulation layer 108 includes at least one opening that exposes at least one active area among the active areas 106 of the substrate 102. The opening is then filled with a conductive material to form a direct contact 110. In some embodiments, the direct contact 110 is electrically connected to the corresponding active area 106, and the portion of the active area 106 serves as source region of a transistor.

A plurality of bit line structures 120 protrudes from the substrate 102. In some embodiments, the bit line structures 120 may be regularly arranged at substantially equal intervals from each other over the substrate 102. Each of the bit line structures 120 may include two portions along a vertical direction substantially perpendicular to the substrate 102 (e.g., along Z direction). In some embodiments, the bit line structure 120 includes a conductive layer 122 at lower portion, and an insulation capping layer 124 at upper portion.

The formation of the conductive layer 122 and the insulation capping layer 124 includes forming a conductive material layer and an insulation capping material layer sequentially over the substrate 102. The insulation capping material layer may be formed on the first conductive material layer. In one embodiment, both of the first conductive material layer and the insulation capping material layer may be substantially simultaneously etched to form the conductive layer 122 and the insulation capping layer 124. Thus, the bit line structures 120 including the conductive layer 122 and the insulation capping layer 124 may be spaced apart from each other in a first direction (e.g., the X direction) and extend in parallel with each other along a second direction (e.g., the Y direction). In yet some other embodiments, the insulation capping material layer is etched with desirable patterned and served as a mask pattern on the first conductive material layer. Using the patterned insulation capping material layer as an etch mask, the first conductive material layer is etched to form the conductive layer 122.

In some embodiments, the conductive layer 122 includes at least one material selected from semiconductor with impurities doped thereon, metal, conductive metal nitride, and metal silicide. In some embodiments, the conductive layer 122 may have a stacked structure. For example, the conductive layer 122 may be stacked with materials including doped polysilicon as well as metal nitride or metal such as tungsten, tungsten nitride, and/or titanium nitride. The conductive layer 122 may be electrically connected to the direct contact 110.

In some embodiments, the insulation capping layer 124 includes silicon nitride. A vertical length (e.g., a length along the Z axis) of the insulation capping layer 124 may be greater than that of the conductive layer 122.

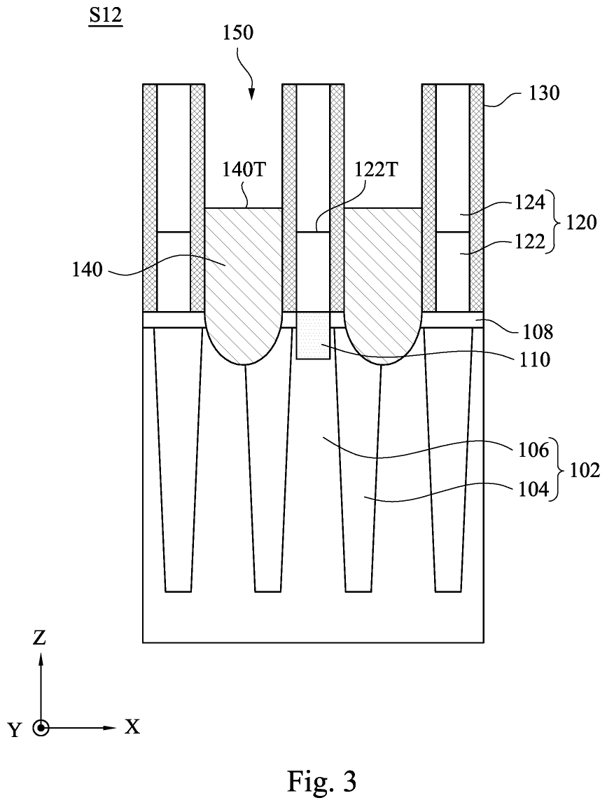

Referring to FIG. 3, the method of forming the semiconductor structure goes to step S12, a plurality of spacer structures 130 are formed on the bit line structures 120, respectively, and a plurality of buried contacts 140 are formed between the bit line structures 120.

The spacer structures 130 extend along sidewalls of the bit line structures 120. The spacer structures 130 may be a single layer structure or multilayer structure. In some embodiments, the spacer structure 130 includes silicon nitride, silicon oxide, or combination thereof. In some embodiments, the spacer structure 130 includes using of sacrificial layer for transforming into an air gap in subsequent fabrication stages. In some embodiments, the spacer structures 130 may be formed by any suitable deposition approaches such as chemical vapor deposition (CVD) techniques, atomic layer deposition (ALD), or physical vapor deposition (PVD) techniques.

After the spacer structures 130 are formed on sidewalls of the bit line structures 120, a plurality of buried contacts 140 are formed between the spacer structures 130 and the bit line structures 120. The formation of the buried contacts 140 includes performing an etching process to form recesses that expose portions of isolation areas 104 of the substrate 102 and portions of active areas 106 of the substrate 102. In some embodiments, the recesses and the spaces above are also regarded as contact holes 150.

Then, a deposition process is performed to fill the exposed isolation areas 104 and the active areas 106 of the substrate 102 with a first conductive material and fill the contact holes 150. Then an etch back process is performed to remove portions of the first conductive material, and the remaining portions of the first conductive material become the buried contacts 140 between the bit line structures 120. The sidewalls of the upper section of the spacer structures 130 are exposed after the etch back process is performed.

In some embodiments, the height of the buried contacts 140 is greater than the height of the conductive layer 122 of the bit line structures 120. That is, the top surface 140T of the buried contacts 140 is higher than the top surface 122T of the conductive layer 122 of the bit line structures 120. In some embodiments, the material of the buried contacts 140 is a silicon-containing material. For example, the material of the buried contacts 140 may include doped polysilicon.

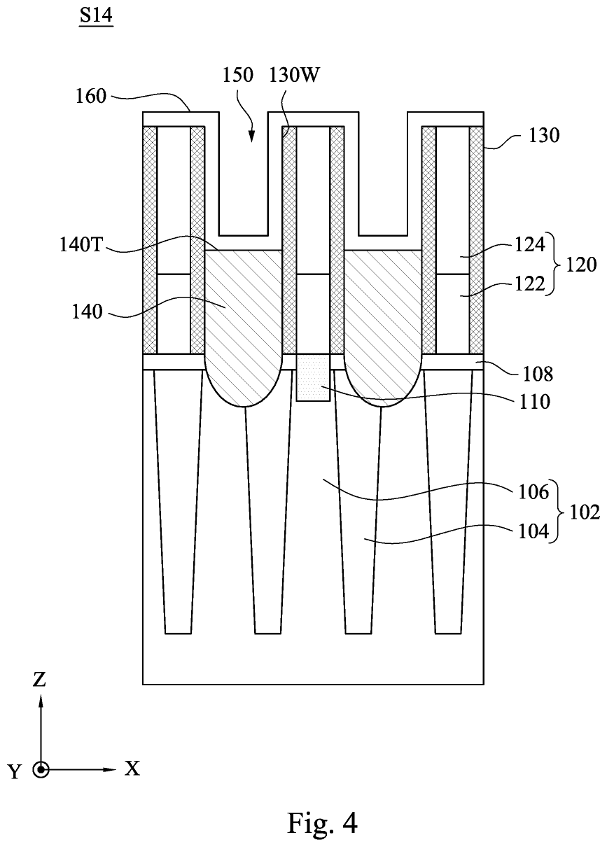

Referring to FIG. 4, the method of forming the semiconductor structure goes to step S14, a barrier layer 160 is conformally deposited on the structure of FIG. 3. In some embodiments, the barrier layer 160 is deposited on the sidewalls 130W of the spacer structures 130 and on the top surfaces 140T of the buried contacts 140. In other words, the barrier layer 160 is deposited lining the upper section of the contact holes 150.

The barrier layer 160 is desired to be deposited with a uniform thickness. The barrier layer 160 is deposited using an advanced sequential flow deposition process which has excellent step coverage capability. The barrier layer 160 may include a metal layer, a metal nitride layer, or a combination thereof. The metal layer includes, for example, titanium, tantalum, or combinations thereof. The metal nitride layer includes, for example, titanium nitride, titanium aluminum nitride, tantalum nitride, or combinations thereof. In some embodiments, the barrier layer 160 is a titanium nitride (TiN) layer.

In some embodiments, the advanced sequential flow deposition process of forming the barrier layer 160 includes one or more cycles. The cycles of the advanced sequential flow deposition process include: providing titanium tetrachloride (TiCl₄) gas to the chamber; introducing a purge gas to remove excess TiCl₄ gas from the chamber; providing ammonia (NH₃) gas to the chamber; and introducing a second purge gas to remove excess NH₃ gas from the chamber. In some embodiments, the advanced sequential flow deposition process includes repeating a plurality of the cycles, and the thickness of the titanium nitride layer can be controlled by the number of cycles. As a result of the advanced sequential flow deposition process, the barrier layer 160 with a uniform thickness covers the sidewalls 130W of the spacer structures 130, the top surfaces 140T of the buried contacts 140, and the top surfaces of the bit line structures 120 and the spacer structures 130.

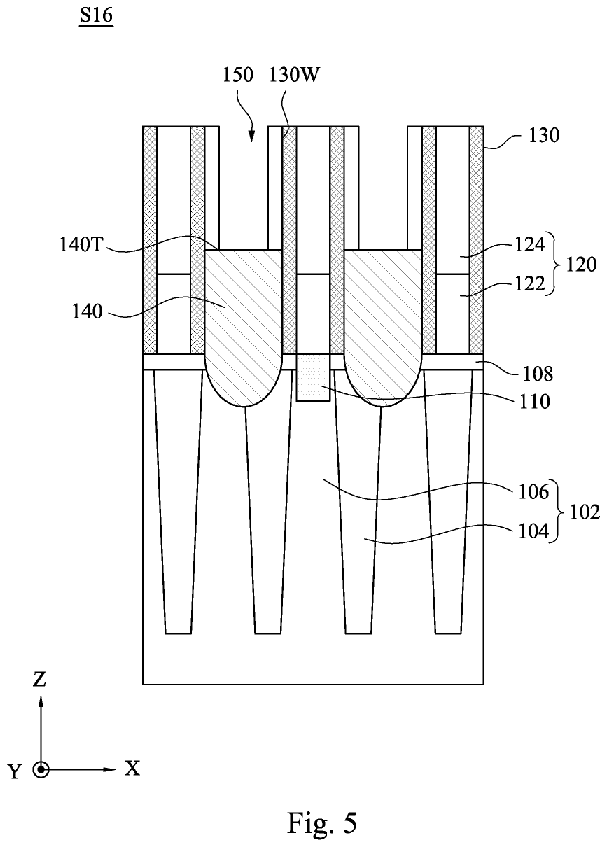

Referring to FIG. 5, the method of forming the semiconductor structure goes to step S16, the portions of the barrier layer 160 on the top surfaces 140T of the buried contacts 140 are removed. In some embodiments, a directional etch back process is performed to remove the portions of the barrier layer 160 on the top surfaces 140T of the buried contacts 140. The top surfaces 140T of the buried contacts 140 are exposed after the directional etch back process, and the sidewalls 130W of the spacer structures 130 are still covered by the barrier layer 160. In some embodiments, the portions of the barrier layer 160 on the top surfaces of the bit line structures 120 and the spacer structures 130 are also removed after the directional etch back process, and the top surfaces of the insulation capping layers 124 of the bit line structures 120 are exposed.

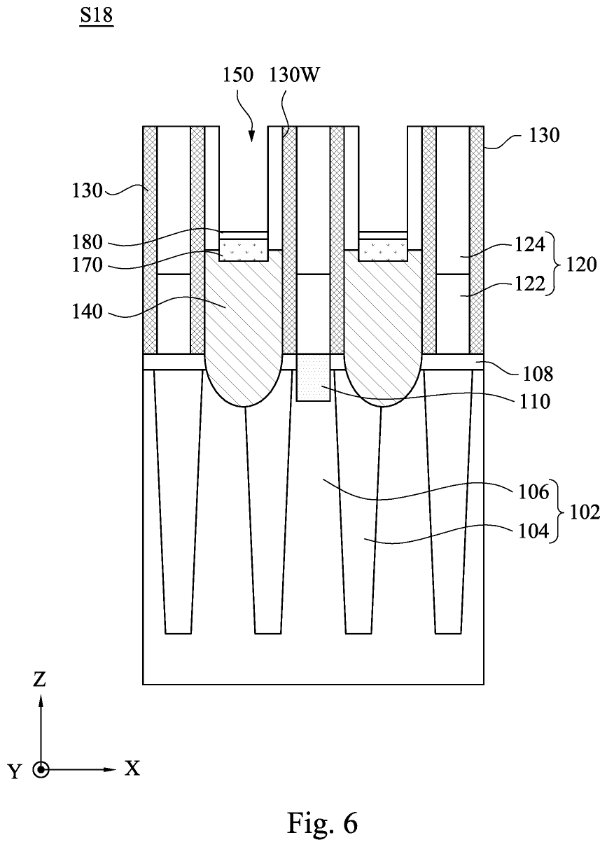

Referring to FIG. 6, the method of forming the semiconductor structure goes to step S18, a plurality of metal silicide layers 170 are formed on the top surfaces of the buried contacts 140, and a plurality of metal layer 180 are formed on the metal silicide layers 170. The formation of the metal silicide layers 170 includes performing a chemical vapor deposition (CVD) process. The CVD process includes providing a metal containing precursor which may be provided to the chamber in the presence of a carrier gas, such as an inert gas. In some embodiments, the metal containing precursor is a titanium (Ti) containing precursor. Titanium is deposited on the top surfaces of the buried contacts 140 and is further reacted with the polysilicon material of the buried contacts 140 thereby forming the metal silicide layers 170 such as titanium silicide layers on the buried contacts 140. The amount of the titanium containing precursor is more than it need to form the metal silicide layers 170. Namely, there is sufficient amount of titanium containing precursor in the chamber, and thin metal layers 180 such as titanium layers are deposited on the metal silicide layers 170 after the forming of the metal silicide layers 170. In some embodiments, the deposition of titanium is a selective deposition process. That is, titanium is deposited on the buried contacts 140 and is not deposited on the barrier layer 160.

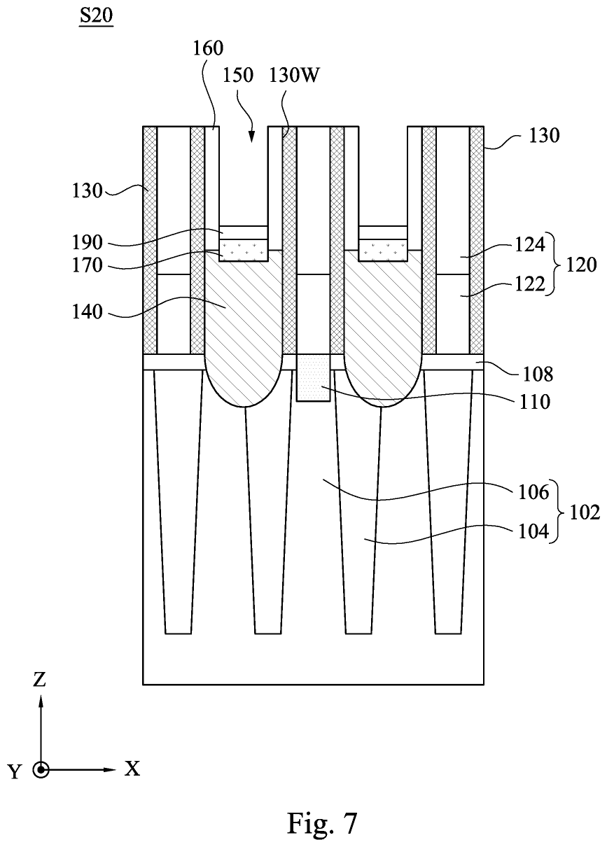

Referring to FIG. 7, the method of forming the semiconductor structure goes to step S20, a nitridation process is performed, and the thin deposited metal layers 180 (see FIG. 6) are transformed to a plurality of metal nitride layers 190 such as titanium nitride layers on the metal silicide layers 170.

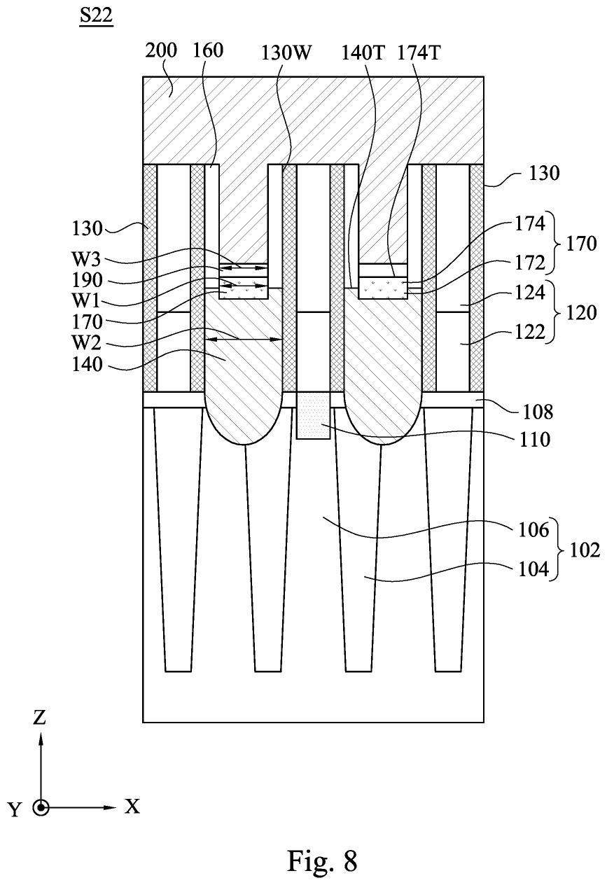

Referring to FIG. 8, the method of forming the semiconductor structure goes to step S22, a second conductive material 200 is deposited filing the contact holes 150 (see FIG. 7). The second conductive material is different from the first conductive material of the buried contacts 140. For example, the first conductive material of the buried contacts 140 can be doped polysilicon, and the second conductive material can be metal such as tungsten. The second conductive material 200 not only fills the contact holes 150, but also covers the top surfaces of the bit line structures 120.

As discussed from FIG. 4 to FIG. 8, the barrier layer 160 on the sidewalls of the spacer structures 130 is deposited by using advanced sequential flow deposition process which has excellent step coverage capability. Therefore, the barrier layer 160 has a uniform thickness, and the issue of overhang such as the thickness of the barrier layer at top of the contact holes is thicker than thickness of the barrier layer at bottom of the contact holes while using conventional CVD process can be prevented. Thus the contact holes 150 would not be partially sealed or wrapped by the barrier layer 160, and the inner diameter of the contact holes 150 is substantially equal from bottom to top of the contact holes 150. As a result, the second conductive material 200 is able to void-free fills the contact holes 150.

Additionally, the layers between the second conductive material 200 and the buried contacts 140 include the metal silicide layers 170 on the buried contacts 140 and the metal nitride layers 190 on the metal silicide layers 170. Comparing with directly form the second conductive material 200 on the buried contacts 140, adding the metal silicide layers 170 and the metal nitride layers 190 therebetween can greatly decrease the contact resistance of the layer stack in the contact holes 150. More particularly, the metal silicide layers 170 such as titanium silicide layer plays an important role to reduce the contact resistance of the buried contacts 140 such as polysilicon and the metal nitride layers 190 such as titanium nitride. The metal nitride layers 190 underlying the second conductive material 200 not only serves as a part of the contact, but also prevent the second conductive material 200 from diffusing.

Reference is made back to FIG. 8. In each of the contact holes 150, the buried contact 140 disposed at the bottom of the contact hole 150, and a portion of the buried contact 140 is inserted into the substrate 102 and contacts the isolation area 104 and the active area 106. The side surface of the buried contact 140 is in contact with the spacer structures 130. The barrier layer 160 is disposed above the buried contact 140 and on the sidewall of the contact holes 150.

The metal silicide layer 170 is disposed on the buried contact 140, and a portion of the metal silicide layer 170 is encircled by the buried contact 140. The metal silicide layer 170 includes a lower section 172 embedded in the buried contact 140 and an upper section 174 protruded from the buried contact 140. The bottom surface and the side surface of the lower section 172 of the metal silicide layer 170 is in contact with the buried contact 140, and the side surface of the upper section 174 of the metal silicide layer 170 is in contact with the barrier layer 160. The top surface 174T of the upper section 174 of the metal silicide layer 170 is higher than the top surface 140T of the buried contact 140. The width W1 of the metal silicide layer 170 is less than the width W2 of the buried contact 140.

The metal nitride layer 190 is disposed on the metal silicide layer 170. The side surface of the metal nitride layer 190 is in contact with the barrier layer 160. The width W3 of the metal nitride layer 190 is equal to the width W1 of the metal silicide layer 170. The width W3 of the metal nitride layer 190 is less than the width W2 of the buried contact 140. Because the metal nitride layer 190 and the barrier layer 160 are formed by different processes, there is an interface present between the metal nitride layer 190 and the barrier layer 160.

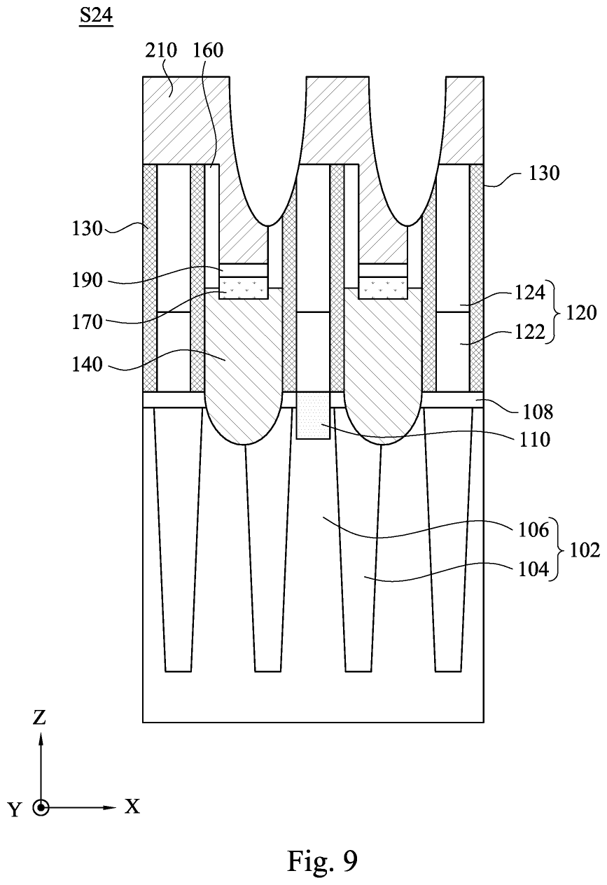

Referring to FIG. 9, the method of forming the semiconductor structure goes to step S24, an etching process is performed to define a plurality of landing pads 210. The etching process includes forming a mask pattern (not shown) on the second conductive material 200. Subsequently, the second conductive material 200 is etched with the mask pattern as an etch mask. In some embodiments, portions of the bit line structures 120 and the spacer structures 130 disposed on the sidewalls thereof may be removed as well. After etching, the landing pads 210 are defined and may be separated from each other by a hole. In some embodiments, the landing pads 210 cover the top surface of the bit line structures 120 and contact the insulation capping layers 124.

According to some embodiments of the disclosure, the contact structures including the landing pads 210, the metal nitride layers 190, the metal silicide layers 170, and the buried contacts 140 in the contact holes 150, formed by above fabricating steps, can provide benefit of both void-free filling and low contact resistance.

It will be apparent to those skilled in the art that various modifications and variations can be made to the structure of the present disclosure without departing from the scope or spirit of the disclosure. In view of the foregoing, it is intended that the present disclosure cover modifications and variations of this invention provided they fall within the scope of the following claims and their equivalents.

What is claimed is:

1. A semiconductor device comprising:
a substrate comprising a plurality of active regions and an isolation region between the active regions;
a plurality of bit line structures disposed on the active regions;
a plurality of spacer structures disposed on sidewalls of the bit line structures;
a buried contact disposed between the bit line structures;
a barrier layer disposed above the buried contact and on sidewalls of spacer structures;
a metal silicide layer disposed on the buried contact;
a metal nitride layer disposed on the metal silicide layer; and
a landing pad disposed on the metal nitride layer.

2. The semiconductor device of claim 1, wherein a side surface of the buried contact is in contact with the spacer structures.

3. The semiconductor device of claim 1, wherein the metal silicide layer comprises a lower section and an upper section, the lower section is embedded in the buried contact, and the upper section is protruded from the buried contact.

4. The semiconductor device of claim 3, wherein a side surface of the upper section is in contact with the barrier layer.

5. The semiconductor device of claim 3, wherein a top surface of the upper section is higher than a top surface of the buried contact.

6. The semiconductor device of claim 1, wherein a width of the metal silicide layer is less than a width of the buried contact.

7. The semiconductor device of claim 1, wherein a side surface of the metal nitride layer is in contact with the barrier layer, and an interface is present between the metal nitride layer and the barrier layer.

8. The semiconductor device of claim 1, wherein the buried contact comprises polysilicon, the metal silicide layer is a titanium silicide layer, the metal nitride layer is a titanium nitride layer, and the landing pad comprises tungsten.

9. A method of forming a semiconductor device, comprising:
forming a plurality of bit line structures on a plurality of active regions of a substrate;
forming a plurality of spacer structures on sidewalls of the bit line structures;
forming a buried contact between the bit line structures;
forming a barrier layer disposed on a top surface of the buried contact and on sidewalls of spacer structures;
removing a portion of the barrier layer on the top surface of the buried contact to expose the top surface of the buried contact;
forming a metal silicide layer on the buried contact;
forming a metal nitride layer on the metal silicide layer; and
forming a landing pad disposed on the metal nitride layer.

10. The method of claim 9, wherein the barrier layer is formed by performing an advanced sequential flow deposition process.

11. The method of claim 10, wherein the advanced sequential flow deposition process comprises performing a plurality of cycles of following steps:
providing titanium tetrachloride (TiCl₄) gas to a chamber;
introducing a first purge gas to remove excess TiCl₄ gas from the chamber;
providing ammonia (NH₃) gas to the chamber; and
introducing a second purge gas to remove excess NH₃ gas from the chamber.

12. The method of claim 9, wherein the metal silicide layer is formed by performing a selective deposition process to deposit metal on the top surface of the buried contact, and the deposited metal is reacted with a silicon material of the buried contact.

13. The method of claim 12, wherein the selective deposition process further deposits a metal layer on the metal silicide layer.

14. The method of claim 13, further comprising performing a nitridation process to transform the metal layer to a metal nitride layer.

15. The method of claim 9, wherein the buried contact comprises polysilicon, the metal silicide layer is a titanium silicide layer, the metal nitride layer is a titanium nitride layer, and the landing pad comprises tungsten.
